(19) United States
(12) Patent Application Publication
(10) Pub. No.: US 2011/0175238 A1
(43) Pub. Date: Jul. 21, 2011

(54) Method for Producing Semiconductor Chips and Corresponding Semiconductor Chip

(76) Inventor: Stefan Illek, Donaustauf (DE)

(21) Appl. No.: 12/746,096

(22) PCT Filed: Dec. 8, 2008
(86) PCT No.: PCT/DE2008/002056

§ 371 Date: Jun. 24, 2010

(30) Foreign Application Priority Data
Dec. 20, 2007 (DE) 10 2007 061 469.3
Mar. 13, 2008 (DE) 10 2008 014 121.6

(51) Int. Cl. H01L 23/12; H01L 21/50

(52) U.S. Cl. 257/782; 438/113; 257/E21.499; 257/E23.003

(57) ABSTRACT

A method for producing a plurality of semiconductor chips is specified. A plurality of semiconductor bodies is provided on a substrate, wherein the semiconductor bodies are spaced apart from one another by interspaces. A structured carrier is provided, having a plurality of elevations. The structured carrier is positioned relative to the substrate in such a way that the elevations of the structured carrier extend into the interspaces between the semiconductor bodies A mechanically stable assemblage is produced, comprising the substrate and the structured carrier. The assemblage is singulated into a plurality of semiconductor chips.

This patent application is a national phase filing under section 371 of PCT/DE2008/002056, filed Dec. 8, 2008, which claims the priority of German patent applications 10 2007 061 469.3, filed Dec. 20, 2007, and 10 2008 014 121.6, filed Mar. 13, 2008, each of which is incorporated herein by reference in its entirety.

### TECHNICAL FIELD

The present application relates to a method for producing semiconductor chips, and to a semiconductor chip.

### BACKGROUND

During the operation of semiconductor chips, loss processes can lead to great heating of the semiconductor chip. By way of example, in the case of an optically pumped semiconductor laser, for instance a VECSEL (Vertical External Cavity Surface Emitting Laser), temperature increases of more than 150° C. can occur in the active region provided for generating radiation.

In the semiconductor chip, this can lead to a refractive index gradient, which can bring about usually undesirable formation of a so-called “thermal lens”. Furthermore, great increases in the temperature of the semiconductor laser can have the effect that the optical output power of the semiconductor laser does not increase further when the pump power is increased (thermal roll-over).

### SUMMARY

A method makes it possible to produce semiconductor chips in which heat generated in the active region can be dissipated in an improved manner. For example, a semiconductor chip has, particularly with regard to the heat dissipation, improved properties.

In accordance with one embodiment, in a method for producing a plurality of semiconductor chips, a plurality of semiconductor bodies are provided on a substrate, wherein the semiconductor bodies are spaced apart from one another by interspaces. A structured carrier is provided, having a plurality of elevations. The structured carrier is positioned relative to the substrate in such a way that the elevations of the structured carrier extend into the interspaces between the semiconductor bodies. A mechanically stable assemblage is produced, including the substrate and the structured carrier. The assemblage is singulated into a plurality of semiconductor chips.

In this case, the method need not necessarily be carried out in the order stated above.

The method makes it possible to produce, in a simplified manner, semiconductor chips which include a part of the structured carrier and expediently a respective semiconductor body. By means of the structured carrier, a chip carrier is formed which mechanically stabilizes the semiconductor body.

The elevations are provided, in particular, for mechanically stabilizing the chip carriers. In the region between the elevations, that is to say in the regions in which the semiconductor bodies are fixed, the chip carriers can be made particularly thin. Thus, it is possible to produce semiconductor chips in which the thermal resistance of the chip carrier is reduced, whereby the heat generated during the operation of the semiconductor chip can be dissipated from the semiconductor body in an improved manner. The efficiency of the generation of radiation can thus be increased. Furthermore, the risk of formation of a thermal lens in the semiconductor body can be reduced.

Furthermore, the elevations ensure a sufficient stability, such that the semiconductor chips can be reliably mounted. The semiconductor chips can be mounted, for example, in a housing for an optoelectronic component or on a mounting carrier, for instance a printed circuit board.

The semiconductor bodies preferably each have a semiconductor layer sequence, which furthermore preferably includes an active region provided for generating radiation. The semiconductor layer sequence is preferably deposited epitaxially, for instance by means of MBE or MOVPE, on a growth substrate.

In one preferred configuration, the structured carrier is embodied such that it is structured in a lattice-like manner by means of the elevations. This is expedient particularly in the case of a matrix-type arrangement of the semiconductor chips on the substrate.

The assemblage is preferably singulated in the region of the elevations of the structured carrier. In this way, a semiconductor chip with a chip carrier can be produced in which the chip carrier has an increased thickness in the edge region. In other words, the chip carrier can have a reinforcement which is embodied in frame-like fashion and which can run around the semiconductor body in a lateral direction, preferably completely. A low thermal resistance of the chip carrier with at the same time good mechanical stability can thus be obtained in a simplified manner.

In one preferred configuration, the elevations are formed by removal of the carrier material in regions between the elevations. The elevations are preferably formed by means of microstructuring, for instance mechanically, for example, by means of sawing, or chemically, for example, by means of wet-chemical or dry-chemical etching.

The structured carrier preferably contains a material having a high thermal conductivity. Furthermore, the carrier material can preferably be structured reliably and in a simple manner.

In particular, a carrier which contains a semiconductor material or consists of a semiconductor material is suitable. By comparison with metallic carriers, a carrier based on semiconductor material is distinguished by simplified structurability and can furthermore be thinned in a simplified manner. By way of example, the structured carrier can contain silicon, germanium or gallium arsenide or consist of such a material. Silicon, in particular, is distinguished by good microstructurability and is available as a large-area and cost-effective carrier material.

Prior to the singulating step, the assemblage preferably has an interface on which the semiconductor bodies are arranged and furthermore preferably fixed. The elevations are preferably arranged on the same side of the interface as the semiconductor bodies.

In the assemblage, the elevations can project above the semiconductor bodies in a direction running perpendicular to the interface. The larger the perpendicular extent of the elevations, the more stably the semiconductor chip can be made, without increasing the thermal resistance of the chip carrier in the process.

In one preferred configuration, the assemblage is thinned on that side of the interface which is remote from the semiconductor bodies. The thickness of the chip carrier below the semiconductor body can thus be reduced further whilst still in the assemblage.

In one preferred development, the extent of the assemblage perpendicular to the interface on the side remote from the semiconductor bodies, after thinning, is between 5 μm and 70 μm inclusive, preferably between 10 μm and 50 μm inclusive, particularly preferably between 10 μm and 30 μm inclusive. The smaller the vertical extent of the chip carrier below the semiconductor body, the lower the thermal resistance of the chip carrier. On the other hand, by means of a larger extent along this direction, the mechanical stability of the chip carrier is promoted.

In one preferred configuration, after thinning, the extent of the assemblage perpendicular to the interface is larger on that side of the interface which faces the semiconductor bodies than on the side remote from the semiconductor bodies. By means of the thinning, therefore, semiconductor chips can be produced in which the chip carrier has a particularly small thickness in the region of the semiconductor body, and at the same time the chip carrier has a high mechanical stability on account of the comparatively large vertical extent on that side of the interface which faces the semiconductor body.

In one preferred development, after thinning, the extent of the assemblage perpendicular to the interface on that side of the interface which faces the semiconductor body is at least 1.5 times as large, particularly preferably at least twice as large, as on the side remote from the semiconductor body. The mechanical stability of the chip carrier with at the same time good heat dissipation can thus be increased further.

In one configuration variant, the interface is formed by means of the structured carrier. The semiconductor bodies are therefore arranged on the structured carrier.

Furthermore, the chip carriers formed by means of the structured carrier can be embodied in integral fashion in each case.

In one preferred development, the elevations are spaced apart from the substrate during the production of the assemblage. The positioning of the substrate with the semiconductor bodies relative to the structured carrier can therefore be effected in such a way that the semiconductor bodies are fixed to the interface, wherein the elevations do not extend completely into the interspaces of the substrate. A free space thus remains between the elevations of the structured carrier and the substrate in the region of the interspaces. In the assemblage, the mechanical connection of substrate and structured carrier can accordingly be effected exclusively by means of the semiconductor bodies.

In one preferred configuration, the interspaces are formed prior to the positioning of the structured carrier relative to the substrate such that the interspaces extend into the substrate. The substrate is therefore already prestructured when the assemblage is formed. Preferably, the interspaces extend at least 10 μm particularly preferably at least 20 μm, into the substrate.

The substrate can be the growth substrate for the semiconductor layer sequence. The interspaces therefore extend not only into the, preferably epitaxially grown semiconductor layer sequence of the semiconductor body, but also into the growth substrate.

The lateral arrangement of the interspaces and of the elevations is expediently adapted to one another in such a way that the substrate and the structured carrier can intermesh in a comb-like manner.

After the assemblage has been produced, the growth substrate can be thinned or removed at least in regions. In this case, the semiconductor bodies can be mechanically stabilized by means of the structured carrier. The growth substrate is no longer necessary for this purpose.

A semiconductor chip in which the growth substrate is thinned or removed at least in regions is also referred to as a thin-film semiconductor chip.

A thin-film semiconductor chip, for instance a thin-film light emitting diode chip, can furthermore be distinguished in the context of the present application by at least one of the following characteristic features:

at a first main area—facing a carrier element, for instance the chip carrier—of a semiconductor body comprising a semiconductor layer sequence with an active region, in particular an epitaxial layer sequence, a mirror layer is applied or formed, for instance in a manner integrated as a Bragg mirror in the semiconductor layer sequence, and reflects at least part of the radiation generated in the semiconductor layer sequence back into the latter;

the semiconductor layer sequence has a thickness in the range of 20 μm or less, in particular in the region of 10 μm; and/or

the semiconductor layer sequence contains at least one semiconductor layer with at least one area which has an intermixing structure which is preferably embodied as an optical intermixing structure and which furthermore ideally leads to an approximately ergodic distribution of the light in the semiconductor layer sequence, that is to say that it has an as far as possible ergodically stochastic scattering behavior.

A basic principle of a thin-film light emitting diode chip is described, for example, in I. Schnitzer et al., Appl. Phys. Lett. 63 (16), Oct. 18, 1993, 2174-2176, the disclosure content of which in this respect is hereby incorporated by reference in the present application.

In a further preferred configuration, the structured carrier is thinned in the assemblage in such a way that the thickness of the structured carrier in the region between the elevations is between 5 μm and 70 μm inclusive, preferably between 10 μm and 50 μm inclusive, particularly preferably between 10 μm and 30 μm inclusive. The thickness of the structured carrier, the thickness being critical for the heat dissipation in the region of the semiconductor chips, can be reduced by the thinning, whereby the performance of the semiconductor chips can be increased.

In one preferred development, before the mechanically stable assemblage is produced, a connecting layer is applied to the semiconductor body and/or to the interface, for instance to the structured carrier between the elevations. The connecting layer can contain a solder or an adhesive, for example.

It is further possible to provide a wetting layer between the interface and the semiconductor bodies. A mechanically stable fixing of the semiconductor bodies can be obtained in a simplified manner by means of the wetting layer. In particular, the connecting layer can be applied to the semiconductor bodies and the wetting layer can be applied to the interface, or vice versa.

In an alternative configuration variant, the interface is formed by means of the substrate. In this case, the semiconductor bodies are preferably already arranged on the substrate before the production of the mechanically stable assemblage, and furthermore preferably fixed to the substrate. In this case, the substrate is preferably different from the growth substrate for the semiconductor layer sequence. After the semiconductor bodies have been fixed, the growth substrate for the semiconductor layer sequence can be removed or thinned in regions or completely. In this case, the semiconductor bodies can be mechanically stabilized by the substrate.

The substrate preferably contains a material having a high thermal conductivity. By way of example, the substrate can contain a semiconductor, for instance silicon, germanium or gallium arsenide, or consist of such a material.

Alternatively or supplementarily, the substrate can contain a metal, for instance nickel, molybdenum or tantalum, or consist of metal. Such a substrate can be distinguished by a high stability even with very small thicknesses.

Furthermore, the substrate can also contain a ceramic, for instance aluminum nitride or boron nitride. A ceramic material can have a high mechanical stability with at the same time a high thermal conductivity.

In one preferred development, the structured carrier is spaced apart from the semiconductor bodies in the region between the elevations in the assemblage. The structured carrier therefore does not directly adjoin the semiconductor bodies in the assemblage.

The elevations of the structured carrier are preferably cohesively connected to the substrate during the production of the assemblage. In the case of a cohesive connection, the, preferably prefabricated, connection partners are held together by means of atomic and/or molecular forces. The cohesive connection is preferably formed by means of a fixing layer, for instance an adhesive or a solder. The elevations can therefore be connected to the substrate by means of the fixing layer during the production of the assemblage.

In one preferred configuration, the structured carrier is completely removed in the region between the elevations after the production of the assemblage. Consequently, only the elevations of the structured carrier remain in the assemblage.

The chip carrier can be formed by means of the substrate and the elevations fixed to the substrate by means of the connecting layer. By means of the mechanical stabilization by the elevations, the chip carrier can be formed in such a way that the substrate on which the semiconductor body is arranged can be substantially thinned. The risk of fracture for such a thin substrate is reduced by means of the reinforcement by the elevations.

In one preferred development, the substrate in the assemblage is thinned in such a way that the thickness of the substrate is between 5μm and 70 μm inclusive, preferably between 10 μm and 50 μm inclusive, particularly preferably between 10 μm and 30 μm inclusive. The thickness of the chip carrier below the semiconductor chip can thus be reduced in a simple manner. Heat generated during operation in the semiconductor body, in particular, in the active region, can thus be dissipated from the semiconductor chip through the chip carrier in an improved manner. As a result of improved heat dissipation, the temperature in the semiconductor body, in particular, in the active region, can be reduced during operation. Thermally induced losses during the generation of radiation, for instance on account of increased non-radiative recombination, can thus be reduced. Furthermore, the formation of a thermal lens in the semiconductor body can be reduced.

The thinning of the assemblage, in particular, the thinning of the substrate and/or the thinning of the structured carrier, and/or, if appropriate, the removal or thinning of the growth substrate can be effected, in particular, mechanically, for instance by means of grinding, lapping or polishing, and/or chemically, for instance by means of wet-chemical or dry-chemical etching. Alternatively or supplementarily, coherent radiation can also be employed, for example, in a laser lift-off (LLO) method.

In accordance with one embodiment, a semiconductor chip has a semiconductor body and a chip carrier with an interface. The semiconductor body is fixed on the interface. The chip carrier has, on that side of the interface which faces the semiconductor body, at least one elevation which projects above the semiconductor body in a direction perpendicular to the interface.

The semiconductor body preferably has a semiconductor layer sequence, which furthermore preferably comprises an active region.

The elevation is provided for mechanically stabilizing the chip carrier. Preferably, the elevation is embodied in such a way that the chip carrier has a small thickness in the region below the semiconductor body. The dissipation of heat generated during the operation of the semiconductor chip through the chip carrier is thus improved.

In contrast to this, in the case of a planar chip carrier, in particular, in the case of a chip carrier based on semiconductor material, having the same thickness, a sufficient mechanical stability would no longer be ensured. By means of the elevation, therefore, that thickness of the chip carrier, which is critical for the heat dissipation, can be more extensively reduced in conjunction with good mechanical stability.

In one preferred configuration, the at least one elevation runs around the semiconductor chip in a lateral direction. The elevation can therefore be embodied in a frame-like manner.

In the region of the semiconductor body, in particular, below the semiconductor body, a thickness of the chip carrier is preferably between 5μm and 70 μm inclusive, particularly preferably between 10 μm and 50 μm inclusive, most preferably between 10 μm and 30 μm inclusive.

In contrast to this, the thickness of conventional planar chip carriers based on semiconductor material is at least 100μm in order to ensure a sufficient mechanical stability. In the region below the semiconductor body, this region being critical for the heat dissipation, the thickness of the chip carrier described is reduced relative to the edge regions of the chip carrier. Even with the same overall height of the chip carrier, therefore, the heat dissipation from the semiconductor body can be considerably improved.

In one preferred configuration, the extent of the chip carrier perpendicular to the interface is larger on that side of the interface which faces the semiconductor body than on the side remote from the semiconductor body. The mechanical stability of the chip carrier is thus predominantly obtained by means of the at least one elevation arranged on the semiconductor body side as viewed from the interface.

Preferably, the extent of the chip carrier perpendicular to the interface on that side of the interface which faces the semiconductor body is at least 1.5 times as large, particularly preferably at least twice as large, as the extent of the chip carrier on that side of the interface which is remote from the semiconductor body.

In one preferred configuration, the maximum lateral extent of the elevation in cross section is preferably between 50 μm and 1 mm inclusive, particularly preferably between 100 μm and 300 μm inclusive. A small size of the chip carrier with at the same time good mechanical stability can be obtained in a simplified manner.

The chip carrier, in particular, the elevation, preferably contains a semiconductor material, for instance silicon, germanium or gallium arsenide, or consists of such a semiconductor material. Silicon, in particular, is distinguished by good microstructurability.

In one configuration variant, the chip carrier has at least two parts, which are connected to one another cohesively, in particular, by means of a fixing layer. The interface preferably runs in a separating plane between the parts of the chip carrier. The chip carrier can have, for example, a carrier part and a stabilization part, wherein a main area of the carrier part forms the interface on which the semiconductor body is arranged. The stabilization part, preferably embodied in a frame-like manner, can be formed by means of the elevation and furthermore be arranged on the same main area of the carrier part as the semiconductor chip.

The stabilization part and the carrier part can be different from one another with respect to the material. Thus, by way of example, the material for the stabilization part can be chosen with regard to good structurability and the material for the carrier part can be chosen with regard to a high thermal conductivity. Preferably, the stabilization part contains one of the semiconductor materials mentioned in connection with the structured carrier, in particular, silicon, or consists of such a material. The carrier part can contain, in particular, one of the materials mentioned in connection with the substrate, for instance a semiconductor such as, for example, germanium, a ceramic or a metal or can consist of such a material.

Alternatively, the stabilization part and the carrier part can be embodied such that they are of identical type with respect to the material.

In an alternative configuration variant, the chip carrier is embodied in integral fashion. A fixing layer between the carrier part and the stabilization part can be dispensed with in this case.

In one preferred configuration, the at least one elevation has, on the semiconductor body side, a side flank which runs perpendicular to the interface. Such a side flank can be produced, in particular, by means of dry-chemical etching.

By means of the perpendicular side flank, the lateral extent of the chip carrier with the same size of the semiconductor body can be minimized.

Alternatively, the at least one elevation can have, on the semiconductor body side, a side flank which runs at an angle that differs from 90° with respect to the interface. Preferably, the elevation in this case tapers with increasing distance with respect to the interface.

The angle with respect to the interface is preferably between 30° and 60° inclusive. Such a side flank can be produced in a simple manner, in particular, by means of wet-chemical etching.

In one preferred development, the chip carrier has a mounting area on that side of the interface which is remote from the semiconductor body, the mounting area being provided for fixing the semiconductor chip. The chip carrier is therefore arranged between the mounting area and the semiconductor body.

The semiconductor chip is preferably provided for generating radiation. In this case, during operation, the semiconductor chip can be optically pumped or can generate radiation when an external electrical voltage is present.

The semiconductor chip furthermore preferably contains a III-V compound semiconductor material. Such compound semiconductor materials are particularly suitable for generating radiation from the ultraviolet through the visible to the infrared spectral range.

The semiconductor chip can be provided for generating coherent radiation and can be embodied, for example, as a surface emitting semiconductor laser, for instance as a VCSEL (Vertical Cavity Surface Emitting Laser), as a VECSEL (Vertical External Cavity Surface Emitting Laser) or as a disk laser. Furthermore, the semiconductor chip can also be embodied as an edge emitting semiconductor laser.

Alternatively or supplementarily, the semiconductor chip can also be provided for generating incoherent radiation. For this purpose, the semiconductor chip can be embodied, for example, as a luminescence diode chip, for instance as a light emitting diode chip (LED chip).

For the generation of partly coherent radiation, the semiconductor chip can be embodied, for example, as an RCLED chip (Resonant Cavity Light Emitting Diode).

The method described further above is particularly suitable for producing the semiconductor chip described. Features described in connection with the method can therefore also be used for the semiconductor chip, and vice versa.

### BRIEF DESCRIPTION OF THE DRAWINGS

Further features, advantageous configurations and expediences will become apparent from the following description of the exemplary embodiments in conjunction with the figures.

FIGS. 1A to 1G show a first exemplary embodiment of a method for producing a plurality of semiconductor chips on the basis of intermediate steps illustrated schematically in sectional view;

FIGS. 2A to 2F show a second exemplary embodiment of a method for producing a plurality of semiconductor chips on the basis of intermediate steps illustrated schematically in sectional view;

FIGS. 3A and 3B show a first exemplary embodiment of a semiconductor chip in schematic sectional view (FIG. 3A) and in associated plan view (FIG. 3B); and

FIGS. 4A and 4B show a second exemplary embodiment of a semiconductor chip in schematic sectional view (FIG. 4A) and associated plan view (FIG. 4B).

Elements which are identical, of identical type and act identically are provided with identical reference symbols in the figures.

The figures are in each case schematic illustrations and therefore not necessarily true to scale. Rather, comparatively small elements and, in particular, layer thicknesses may be represented with an exaggerated size for illustration purposes.

### DETAILED DESCRIPTION OF ILLUSTRATIVE EMBODIMENTS

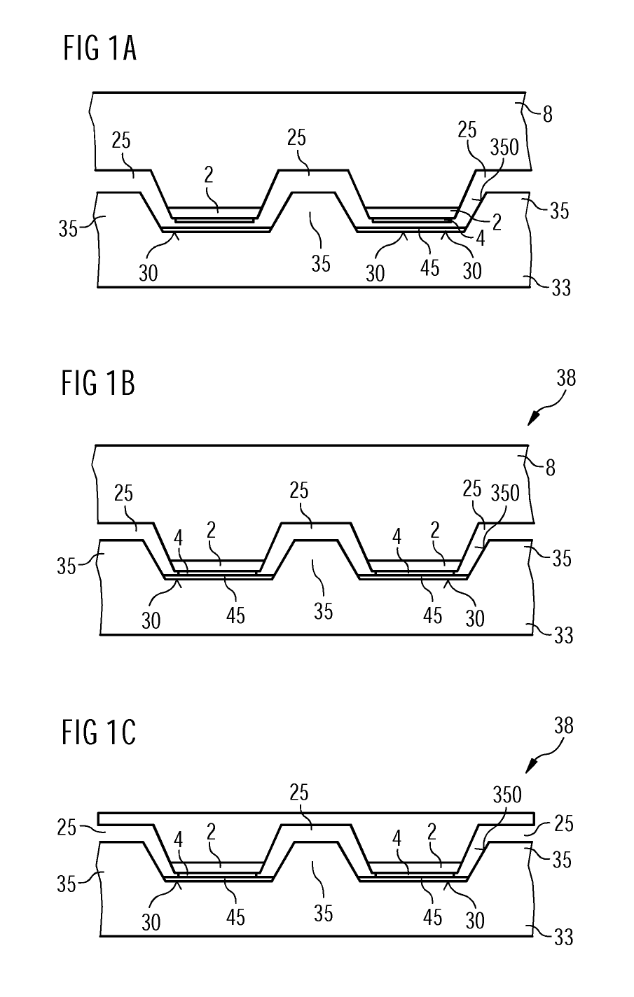

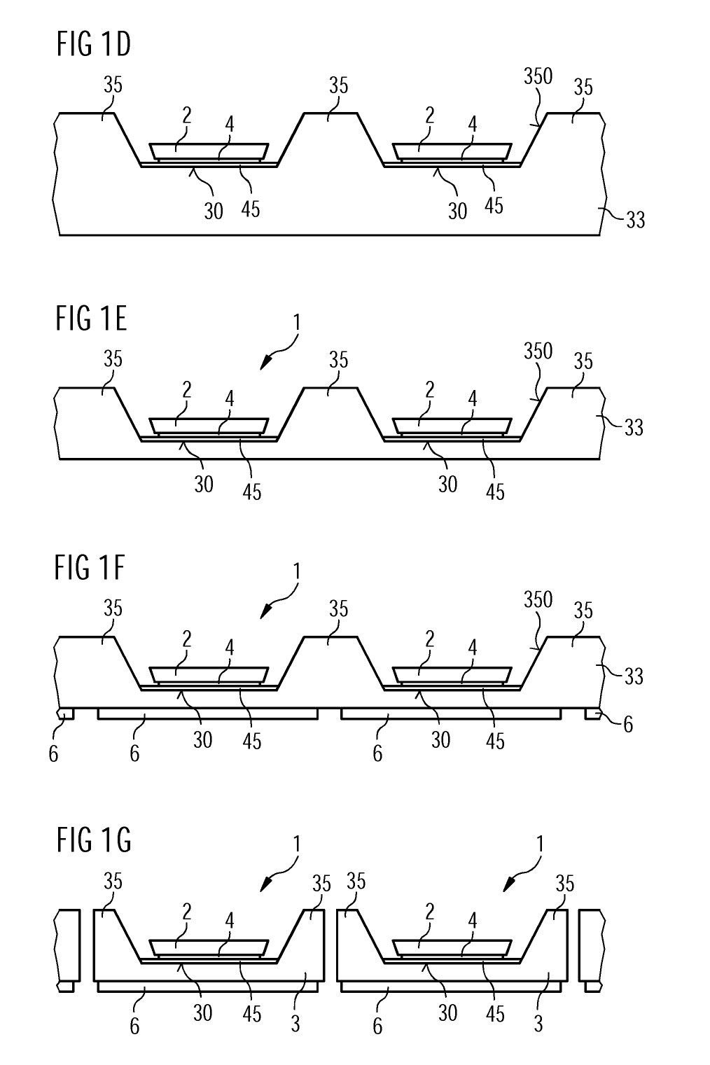

FIG. 1A shows an excerpt from a substrate 8, on which a plurality of semiconductor bodies 2 are provided. Two semiconductor bodies 2 are arranged alongside one another in the excerpt illustrated.

The semiconductor bodies 2 preferably each comprise a semiconductor layer sequence. An active region provided for generating radiation can be formed (not explicitly illustrated) in the semiconductor layer sequence. The semiconductor layer sequence is preferably produced epitaxially, for instance by means of MOVPE or MBE. In this case, the substrate 8 can serve as a growth substrate for the semiconductor layer sequence of the semiconductor body 2. In a departure from this, however, the semiconductor bodies can also be provided on a substrate which is different from the growth substrate.

The semiconductor bodies 2 are spaced apart from one another in a lateral direction by interspaces 25. The interspaces 25 extend into the substrate 8 on the semiconductor body side. The interspaces 25 can extend at least 10 μm, preferably at least 20 μm, into the substrate. The interspaces 25 can be produced, in particular, chemically, for instance by means of wet-chemical or dry-chemical etching. A connecting layer 4 is formed on that side of the semiconductor body 2 which is remote from the substrate 8. By means of the connecting layer 4, the semiconductor bodies 2 can be fixed to a carrier in a simplified manner.

The connecting layer 4 can be embodied as a solder layer, for example, and can furthermore preferably contain a metal, for instance gold, tin or indium, or a metallic alloy, in particular, comprising at least one of the metals mentioned.

Furthermore, FIG. 1A illustrates an excerpt from a structured carrier 33 having a plurality of elevations 35. The elevations are preferably produced by microstructuring, wherein the carrier material of a preferably planar carrier is removed between the elevations 35. The removal can be effected, for example, mechanically and/or chemically, for instance by means of wet-chemical or dry-chemical etching.

The structured carrier preferably contains a material distinguished by good microstructurability, good thermal conductivity and/or a high mechanical stability or consists of such a material.

In particular, the structured carrier preferably contains a semiconductor material or consists of a semiconductor material. Silicon, germanium or gallium arsenide is suitable, by way of example.

The structured carrier 33 has an interface 30 provided for fixing the semiconductor bodies 2 to the structured carrier 33. A wetting layer 45 is formed on the interface 30. By means of the wetting layer, a mechanically stable fixing of the semiconductor bodies 2 to the structured carrier 33 can be produced in a simplified manner. The wetting layer 45 can be formed in the region between the elevations 35 or extend over the whole area of the structured carrier.

As illustrated in FIG. 1B, the substrate 8 with the interspaces 25 already formed between the semiconductor bodies 2 and the structured carrier 33 are positioned with respect to one another in such a way that the elevations 35 of the structured carrier 33 extend into the interspaces 25. The substrate 8 and the structured carrier 33 therefore intermesh in a comb-like manner. A mechanically stable assemblage 38 comprising the structured carrier 33 and the substrate 8 is produced by means of the connecting layer 4. The extent of the elevations 35 is adapted to the interspaces 25 in a vertical direction, that is to say in a direction running perpendicular to a main extension plane of the structured carrier 33, in such a way that the elevations 35 are spaced apart from the substrate 8 in the assemblage. Therefore, substrate 8 is mechanically connected to the structured carrier 33 only by means of the semiconductor bodies 2. Subsequent removal of the substrate 8 is thus simplified.

The elevations 35 are therefore already formed before the assemblage 38 is produced. The elevations 35 can have, on the semiconductor body side, side flanks 350 running obliquely with respect to the interface 30. Preferably, the angle with respect to the interface 30 is between 30° and 60° inclusive. By way of example, in the case of a carrier composed of silicon, an angle of approximately 54° can be produced in a simple manner by means of anisotropic wet-chemical etching.

After the assemblage has been produced, the substrate 8 can be removed, as illustrated in FIGS. 1C and 1D. In the exemplary embodiment shown, the removal is effected firstly, as shown in FIG. 1C, in a mechanical step, wherein the substrate 8 is thinned to a residual thickness. The mechanical thinning can be effected for example by means of grinding, lapping or polishing.

The remaining part of the substrate 8 can be removed in a subsequent, preferably chemical, step. This can be effected, for example, by means of wet-chemical or dry-chemical etching. After the removal of the substrate 8, adjacent semiconductor bodies 2 are mechanically connected to one another only by means of the structured carrier 33.

The elevations 35 project above the semiconductor bodies 2 in a vertical direction. The structured carrier 33 now serves for mechanically stabilizing the semiconductor bodies 2. The substrate 8 is no longer necessary for this purpose.

The structured carrier 33 can be thinned on the side remote from the semiconductor bodies 2. Preferably, the structured carrier 33 is thinned in such a way that the thickness of the structured carrier in the region between the elevations is between 5 μm and 70 μm inclusive, preferably between 10 μm and 50 μm inclusive, most preferably between 10 μm and 30 μm inclusive. In this case, the elevations 35 serve for mechanically stabilizing the structured carrier 33. In the region below the semiconductor bodies 2, the structured carrier 33 can thus be thinned to a thickness with which a sufficient mechanical stability would no longer be ensured without the elevations, that is to say in the case of a planar carrier.

Relative to the interface 30, the extent of the assemblage 38 after thinning can be larger on the side facing the semiconductor bodies 2 than on the side remote from the semiconductor bodies. Preferably, after thinning, the extent of the assemblage 38 perpendicular to the interface 30 on that side of the interface which faces the semiconductor body is at least 1.5 times as large, particularly preferably at least twice as large, as on the side remote from the semiconductor bodies.

On the thinned structured carrier 33, mounting layers 6 see FIG. 1F) can be formed on the side remote from the semiconductor bodies 2. In this case, preferably each region of the assemblage 38 from which a semiconductor chip emerges has a respective mounting layer. The mounting layer 6 is provided for a simplified fixing of the semiconductor chips, for example, on a printed circuit board, a heat sink or in a housing for an optoelectronic component.

The mounting layer preferably contains a metal, for example, gold, platinum, titanium, silver, aluminum or indium, or a metallic alloy comprising at least one of the materials mentioned.

As illustrated in FIG. 1G, the assemblage 38 is singulated into a plurality of separate semiconductor chips 1. The singulation can be effected, for example, by means of cleaving, breaking or sawing. A chemical method, for instance wet-chemical or dry-chemical etching, can also be used for the singulation.

In this case, the singulation is effected in the regions of the structured carrier 33 in which the elevations 35 are formed. A sufficient mechanical stability of the structured carrier 33 can thus be ensured in a simple manner.

In the method described, the fixing of the semiconductor bodies 2 to the respective chip carriers 3 can therefore be effected whilst still in the wafer assemblage, such that a multiplicity of semiconductor chips can be produced simultaneously by means of the method.

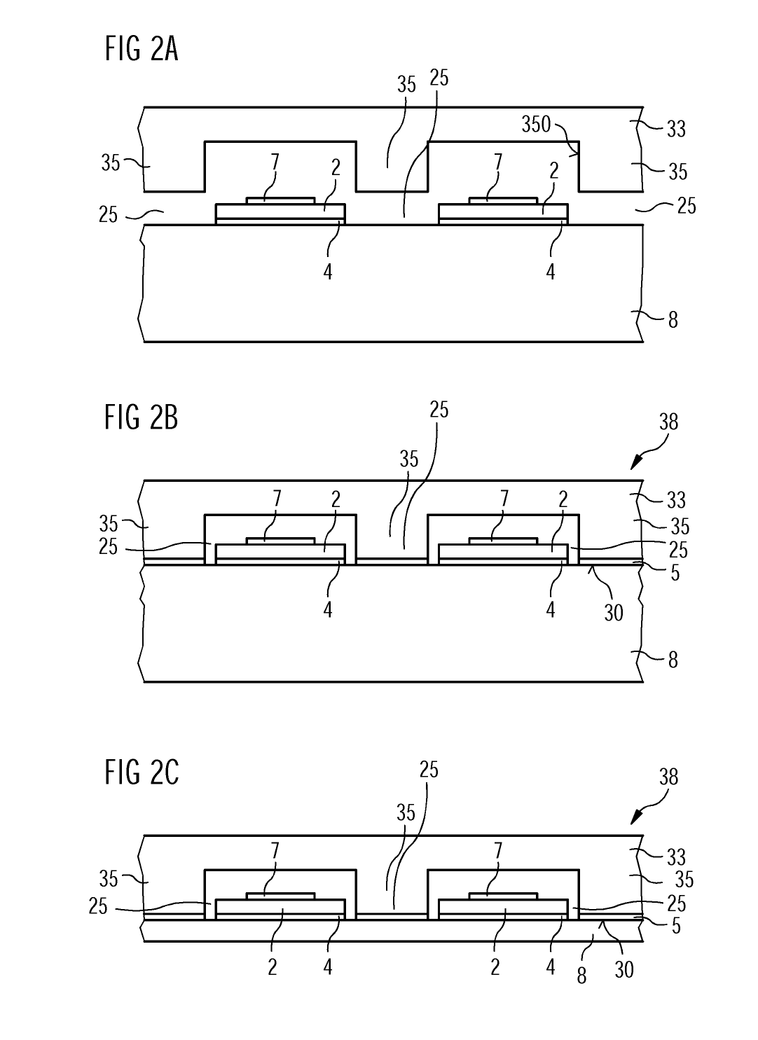

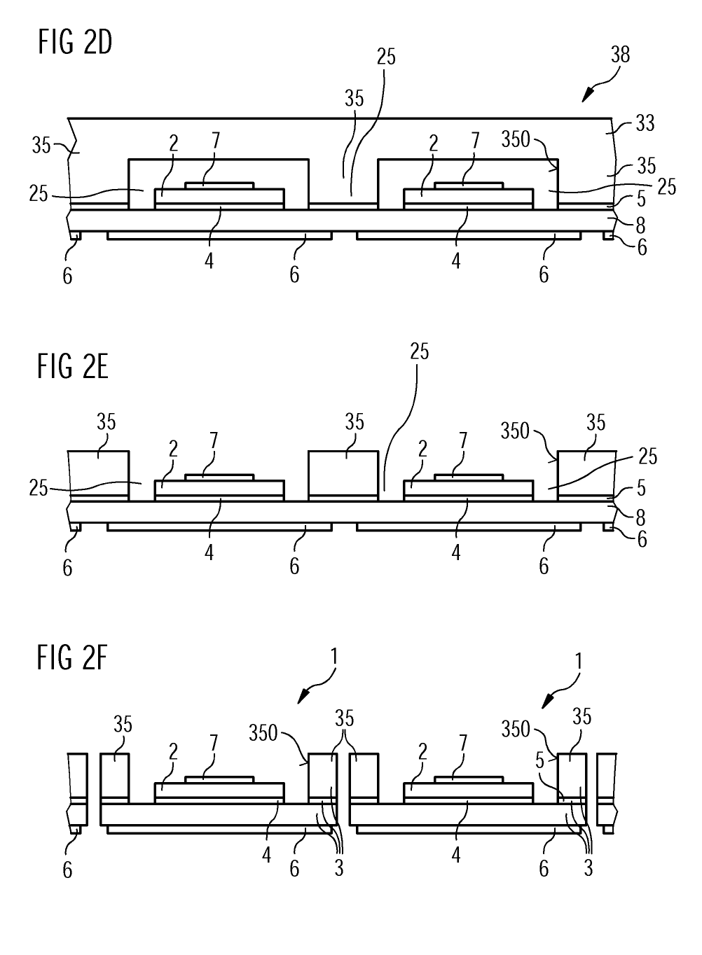

A second exemplary embodiment of a method for producing a plurality of semiconductor chips is illustrated on the basis of the intermediate steps illustrated in schematic sectional view in FIGS. 2A to 2F.

As illustrated in FIG. 2A, a plurality of semiconductor bodies 2 are provided on a substrate 8. The semiconductor bodies are arranged alongside one another. The semiconductor bodies are in each case spaced apart from one another by interspaces 25.

The interspaces 25 extend as far as an interface 30 (see FIG. 2B) on which the semiconductor bodies 2 are arranged.

The semiconductor bodies 2 are fixed to the substrate 8 by means of a connecting layer 4. The substrate 8 is therefore different from the growth substrate for the semiconductor layer sequence of the semiconductor bodies 2.

The substrate preferably contains a material having a high thermal conductivity. By way of example, the substrate can contain a semiconductor, for instance silicon, germanium or gallium arsenide, or consist of such a material.

Alternatively or supplementarily, the substrate can contain a metal, for instance nickel, molybdenum or tantalum, or consist of metal. Such a substrate can be distinguished by a high stability even with very small thicknesses.

Furthermore, the substrate can also contain a ceramic, for instance aluminum nitride or boron nitride. A ceramic material can have a high mechanical stability with at the same time a high thermal conductivity.

In this case, the fixing of the semiconductor bodies 2 to the, preferably planar, substrate 8 can be effected in the wafer assemblage. In other words, after the epitaxial growth of the semiconductor layer sequence from which the semiconductor bodies 2 emerge on the growth substrate, the semiconductor layer sequence is fixed to the substrate 8. After the process of fixing to the substrate 8, the growth substrate can be removed from the semiconductor layer sequence, such that the semiconductor layer sequence remains on the substrate 8. The removal of the growth substrate can be effected mechanically and/or chemically. Coherent radiation can also be employed, for instance in a laser lift-off method.

After the removal of the growth substrate, the interspaces 25 can be formed by means of wet-chemical or dry-chemical etching.

On that side of the semiconductor bodies 2 which is remote from the substrate 8, a respective contact layer 7 is arranged on the semiconductor bodies 2. The contact layer 7 serves for externally making electrical contact with the semiconductor bodies 2. The contact layer can be produced, for example, by means of vapor deposition or sputtering and furthermore preferably contains a metal or a metallic alloy. Particularly in the case of semiconductor chips which are not provided for operation with an electrical external voltage, the contact layer can also be dispensed with.

If appropriate, after the removal of the growth substrate, still further fabrication steps can be carried out at the semiconductor bodies 2. By way of example, that surface of the semiconductor bodies 2 which is respectively remote from the substrate 8 can be provided with a roughening. In the case of an LED semiconductor chip, the coupling-out efficiency of the radiation generated can thus be improved.

Furthermore, a structured carrier 33 is provided, having a plurality of elevations 35. In this case, the structuring of the structured carrier 33 can be effected, in particular, as described in connection with FIG. 1A. Elevations 35 having vertically running side flanks 350 are preferably produced by means of dry-chemical etching.

As illustrated in FIG. 2B, the structured carrier 33 and the substrate 8 are positioned with respect to one another in such a way that the elevations 35 extend into the interspaces 25. The structured carrier 33 and the substrate 8 are cohesively connected to one another by means of a fixing layer 5. The fixing layer 5 can contain an adhesive or a solder, for example.

In contrast to the first exemplary embodiment described in connection with FIGS. 1A to 1G, in this exemplary embodiment the interface 30 on which the semiconductor bodies 2 are arranged is formed by means of a planar surface of the substrate 8. The elevations 35 and the semiconductor bodies 2 are arranged on this interface 30 of the substrate 8.

In the assemblage 38, the structured carrier 33 is spaced apart from the semiconductor bodies 2 in the region between the elevations 35. Therefore, the semiconductor bodies 2 and the structured carrier 33 are mechanically connected to one another only by means of the substrate 8 and the fixing layer 5.

After the assemblage 38 has been produced, the substrate 8 can be thinned on that side of the interface which is remote from the semiconductor bodies 2. An assemblage 38 with a thinned substrate is illustrated schematically in FIG. 2C.

The substrate 8 is preferably thinned in the assemblage 38 in such a way that the thickness of the substrate is between 5 μm and 70 μm inclusive, preferably between 10 μm and 50 μm inclusive, particularly preferably between 10 μm and 30 μm inclusive.

The mechanical stability of the assemblage 38 is ensured by the elevations 35. Thus, the substrate 8 can be thinned to a thickness which would no longer suffice for a sufficient mechanical stabilization in the case of a planar substrate without the elevations.

As an alternative to thinning the substrate, the substrate can also be provided in a manner already having the desired final thickness. This is expedient, in particular, for a substrate which can be thinned only with comparative difficulty, for instance for a metal-containing or ceramic-containing substrate.

A mounting layer 6 can be applied on the thinned substrate, as described in connection with FIG. 1F. This is illustrated schematically in FIG. 2D.

As shown in FIG. 2E, the structured carrier 33 is thinned in such a way that the structured carrier is completely removed in the region between the elevations 35.

This removal of the structured carrier 33 in regions can be effected mechanically and/or chemically.

As illustrated in FIG. 2F, the assemblage 38 is singulated into a plurality of semiconductor chips 1. The singulation can be effected as described in connection with FIG. 1G.

The method described need not necessarily be carried out in the order indicated. By way of example, the mounting layers 6 can be applied before the structured carrier 33 is thinned.

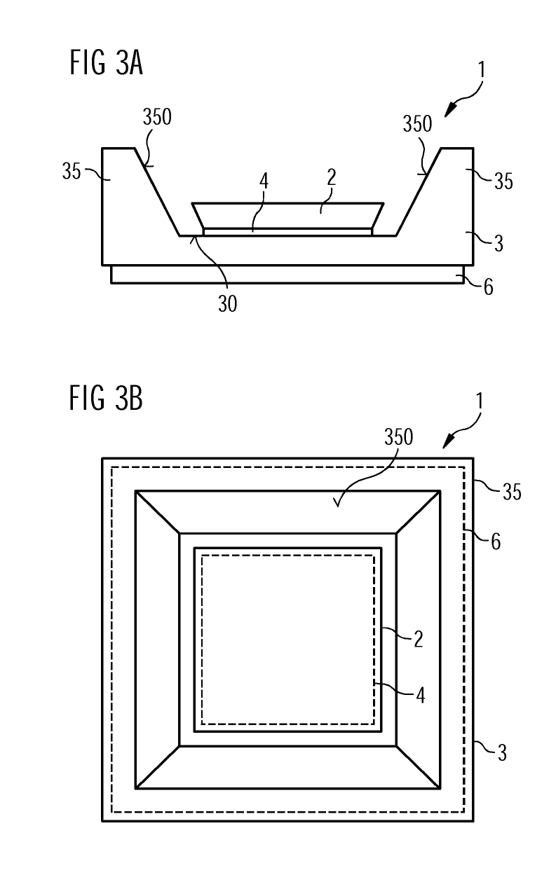

FIGS. 3A and 3B show a first exemplary embodiment of a semiconductor chip in schematic sectional view (FIG. 3A) and in associated schematic plan view (FIG. 3B).

The semiconductor chip 1 comprises a semiconductor body 2 and a chip carrier 3. The chip carrier is therefore part of the semiconductor chip and mechanically stabilizes the semiconductor body 2. The chip carrier 3 is embodied in planar fashion on the side remote from the semiconductor body 2. Mounting of the semiconductor chip 1 is thus simplified.

The semiconductor body 2 includes a semiconductor layer sequence having an active region provided for generating radiation (not explicitly illustrated). The semiconductor layer sequence can form the semiconductor body 2. A growth substrate for the semiconductor layer sequence of the semiconductor body 2 can be removed. The semiconductor chip 1 can therefore be embodied as a thin-film semiconductor chip.

The semiconductor body 2 is arranged on an interface 30 of the chip carrier 3 by means of a connecting layer 4.

The chip carrier 3 has an elevation 35, which runs around the semiconductor body 2 in a lateral direction. In this case, the elevation 35 is embodied as a frame-like stabilization. The elevation 35 projects above the semiconductor body 2 in a perpendicular direction. The chip carrier 3 is mechanically stabilized by means of the elevation 35. In this way, the region of the chip carrier which is formed below the semiconductor body 2 can be particularly thin in conjunction with good mechanical stability. Preferably, the chip carrier 3 in the region below the semiconductor body 2 has a thickness of between 5 μm and 70 μm inclusive, preferably between 10 μm and 50 μm inclusive, most preferably between 10 μm and 30 μm inclusive. The thinner the chip carrier 3 in this region, the better heat generated during the operation of the semiconductor chip 1 can be dissipated from the semiconductor body 2. The temperature of the semiconductor body 2, in particular, of the active region, can thus be reduced in a simplified manner during operation.

The vertical extent of the chip carrier 3 on that side of the interface 30 which faces the semiconductor body 2, that is to say the height of the elevation 35, is preferably at least 1.5 times as large, particularly preferably at least twice as large, as on the side remote from the semiconductor body 2. By way of example, the vertical extent of the elevation 35 can be between 50 μm and 80 μm, while the vertical extent of the chip carrier 3 below the semiconductor body 2 has a thickness of just 10 μm to 30 μm. The overall height of the chip carrier 3 is therefore approximately 100 μm.

Relative to the interface 30, the chip carrier 3 therefore has a larger vertical extent on the semiconductor body side than on the opposite side of the interface. The thickness of the chip carrier 3, the thickness being critical for the heat dissipation, is thus reduced. At the same time, the chip carrier 3 has a sufficiently high mechanical stability in order to fix the semiconductor chip 1 at a mounting position provided for the semiconductor chip. The fixing of the semiconductor chip 1 can be effected, for example, on a printed circuit board, on a heat sink or in a housing for an optoelectronic component.

In this exemplary embodiment, the chip carrier 3 is embodied in integral fashion. Furthermore, the chip carrier 3 preferably contains a material having a high thermal conductivity and simultaneously good micromechanical structurability.

Particularly preferably, the chip carrier 3 contains silicon or consists of silicon. Silicon is distinguished by particularly good, for instance mechanical or chemical, stucturability. Other semiconductor materials, such as germanium or gallium arsenide, can also be employed.

On that side of the chip carrier 3 which is remote from the semiconductor body 2, the semiconductor chip 1 has a mounting layer 6. The mounting layer 6 serves for simplified mountability of the semiconductor chip 1.

On the semiconductor body side, the chip carrier 3 has a side flank 350 running obliquely with respect to the interface 30. In this case, the elevation 35 tapers with increasing distance with respect to the interface 30.

The elevation 35 preferably has in cross section an extent which is small in comparison with the lateral extent of the semiconductor body 2.

Furthermore, the maximum lateral extent of the elevation 35 in cross section is preferably between 50 μm and 1 mm inclusive, particularly preferably between 100 μm and 300 μm inclusive.

In a plan view of the semiconductor chip 1, the semiconductor body 2 preferably fills a largest possible portion of the base area of the chip carrier 3. The larger this ratio, the larger the proportion of the semiconductor chip area in which radiation can be effectively generated.

In a plan view of the semiconductor chip 1, the semiconductor body 2 preferably covers at least 10% of the base area of the chip carrier 3. By way of example, the base area of the chip carrier 3 can amount to a size of approximately 0.7×0.7 mm² in the case of a size of the semiconductor body of 0.3×0.3 mm². This corresponds to a degree of coverage of approximately 18%.

The semiconductor body 2, in particular, the active region, preferably contains a III-V semiconductor material.

III-V semiconductor materials are particularly suitable for generating radiation in the ultraviolet (Inₓ Ga_{y} Al_{1-x-y} N) through the visible (Inₓ Ga_{y} Al_{1-x-y} N, in particular, for blue to green radiation, or In Ga_{y} Al_{1-x-y} P, in particular, for yellow to red radiation) to the infrared (Inₓ Ga_{y} Al_{1-x-y} As) spectral range. The following in each case holds true here: 0≦x≦1, 0≦y≦1 and x+y≦1, in particular, where x≠1, y≠1, x≠0 and/or y≠0. With III-V semiconductor materials, in particular, from the material systems mentioned, high internal quantum efficiencies can furthermore be obtained in the generation of radiation.

In the exemplary embodiment shown, the semiconductor chip is provided for generating coherent radiation and is embodied as a surface emitting semiconductor laser, for instance as a VECSEL or as a disk laser. For generating radiation, the semiconductor body can be optically pumped. Electrical contacts via which an external electrical voltage can be applied to the semiconductor body are therefore not necessary.

Heat generated during the operation of the semiconductor chip 1 in the active region of the semiconductor body 2 can be effectively dissipated from the semiconductor body through the chip carrier 3. The temperature of the active region is thereby reduced. The risk of a premature thermal roll-over is thus reduced. Furthermore, the formation of a thermal lens in the semiconductor body can be prevented or at least reduced.

On account of the obliquely running side flanks 350, the semiconductor body 2 can be optically pumped in a simplified manner from a direction running obliquely with respect to the vertical direction.

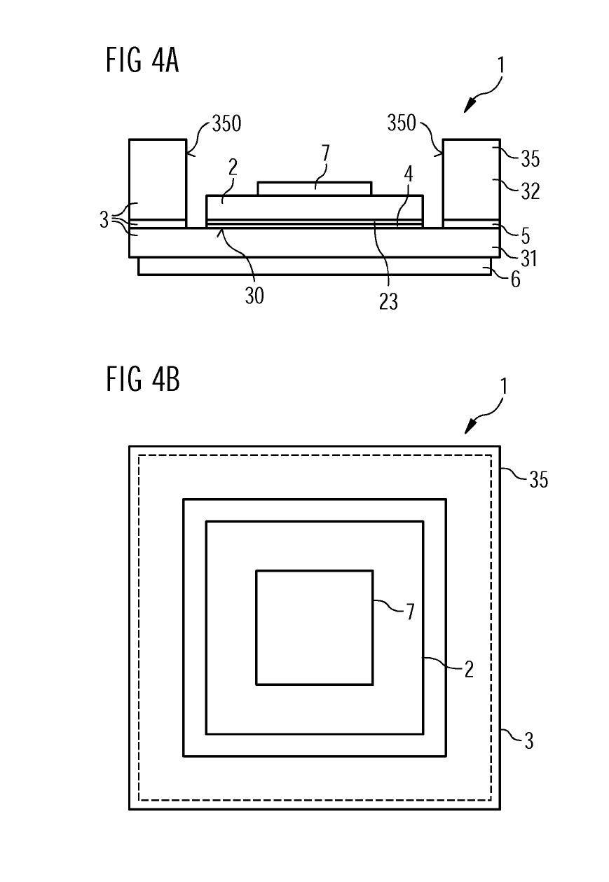

FIGS. 4A and 4B illustrate a further exemplary embodiment of a semiconductor chip 1 in schematic sectional view (FIG. 4A) and associated schematic plan view (FIG. 4B).

This second exemplary embodiment substantially corresponds to the first exemplary embodiment described in connection with FIGS. 3A and 3B. In contrast thereto, the semiconductor body 2 is provided for converting electrical energy into optical radiation power. During the operation of the semiconductor chip 1, charge carriers can be injected into the semiconductor body 2 from opposite sides via a contact layer 7 and via a mounting layer 6. The chip carrier 3 is preferably embodied such that it is electrically conductive for this purpose.

In contrast to the first exemplary embodiment, the chip carrier 3 is embodied in multipartite fashion and has a carrier part 31 and a stabilization part 32. The carrier part 31 and the stabilization part 32 are mechanically stably connected to one another by means of a fixing layer 5. In this case, the stabilization part 32 is formed by means of an elevation 35.

The elevation 35 has a perpendicularly running side flank 350 facing the semiconductor body 2. In a plan view of the semiconductor chip 1, the base area of the chip carrier 3 can thus be reduced for the same area of the semiconductor body 2. In other words, the effective area in which radiation is generated in the semiconductor chip 1 can be enlarged for the same size of the semiconductor chip.

The fixing layer 5 runs along a separating plane in which the interface 30 is formed. The stabilization part 32 and the semiconductor body 2 are arranged on the same surface of the carrier part 31. That is to say that the semiconductor chip 1 is embodied in such a way that the semiconductor body 2 and the stabilization part 32, which realizes the mechanical stability of the semiconductor chip 1, are arranged on the same side of the interface 30 on which the semiconductor body 2 is fixed. In contrast thereto, the mechanical stabilization of the semiconductor body 2 in the case of a conventional semiconductor chip is effected by a thick carrier arranged below the semiconductor body.

A mirror layer 23 is formed between the semiconductor body 2 and the chip carrier 3, preferably between the semiconductor body 2 and the connecting layer 4. The mirror layer 23 preferably has a high reflectivity for the radiation generated in the semiconductor body 2. The mirror layer 23 preferably contains a metal, for instance gold, silver, aluminum or rhodium, or a metallic alloy including at least one of the materials mentioned. The mirror layer is preferably deposited on the semiconductor body, for instance by means of sputtering or vapor deposition.

A barrier layer can be arranged (not explicitly illustrated) between the mirror layer 23 and the connecting layer 4. A diffusion of material of the connecting layer 4 into the mirror layer 23 can be prevented or at least substantially reduced by means of the barrier layer. The barrier layer can contain a metal, in particular, at least one metal from the group consisting of titanium, platinum, tungsten and nickel.

Alternatively or supplementarily, in the semiconductor body 2 a Bragg mirror can be formed by means of a plurality of semiconductor layer pairs arranged one on top of another.

The semiconductor chip 1 with the chip carrier 31 described is distinguished by a particularly low thermal resistance for heat generated in the semiconductor body 2. The heat can thus be dissipated particularly efficiently from the semiconductor chip 1. The construction described is therefore suitable particularly for high-power semiconductor chips, for instance for light emitting diodes having an electrical consumed power of at least 100 mW, preferably at least 300 mW. In this case, the semiconductor chip 1 can also be embodied as an RCLED.

The carrier part 31 and the stabilization part 32 can be different with respect to the material used. In particular, the stabilization part 32 can contain silicon or consist of silicon, while the carrier part 31 can contain a semiconductor other than silicon, for instance Ge or GaAs, a metal, for instance molybdenum, nickel or tantalum, or a ceramic, for instance AN or BN, or can consist of such a material.

The invention is not restricted by the description on the basis of the exemplary embodiments. Rather, the invention encompasses any novel feature and also any combination of features, which in particular includes any combination of features in the patent claims, even if this features or this combination itself is not explicitly specified in the patent claims or the exemplary embodiments.

1. A method for producing a plurality of semiconductor chips, the method comprising:
a) providing a plurality of semiconductor bodies on a substrate, wherein the semiconductor bodies are spaced apart from one another by interspaces;
b) providing a structured carrier having a plurality of elevations;
c) positioning the structured carrier relative to the substrate in such a way that the elevations of the structured carrier extend into the interspaces between the semiconductor bodies;
d) producing a mechanically stable assemblage comprising the substrate and the structured carrier; and
e) singulating the assemblage into a plurality of semiconductor chips.

2. The method as claimed in claim 1, wherein the assemblage, prior to the singulating step, has an interface on which the semiconductor bodies are arranged.

3. The method as claimed in claim 2, further comprising thinning the assemblage on that side of the interface which that is remote from the semiconductor bodies.

4. The method as claimed in claim 3, wherein, after thinning, the extent of the assemblage perpendicular to the interface is larger on that side of the interface that faces the semiconductor bodies than on the side remote from the semiconductor bodies.

5. The method as claimed in claim 2, wherein the interface is formed by means of the structured carrier and the structured carrier is thinned in such a way that a thickness of the structured carrier in a region between the elevations is between 5 μm and 70 μm inclusive.

6. The method as claimed in claim 5, wherein each semiconductor body has a semiconductor layer sequence, wherein the substrate comprises a growth substrate for the semiconductor layer sequence and the growth substrate is thinned or removed at least in regions in the assemblage.

7. The method as claimed in claim 2, wherein the interface is formed by means of the substrate, wherein the semiconductor bodies are fixed to the substrate and a growth substrate for a semiconductor layer sequence of the semiconductor bodies is subsequently removed.

8. The method as claimed in claim 7, further comprising completely removing structured carrier between the elevations after producing the mechanically stable assemblage.

9. The method as claimed in claim 7, wherein the substrate is thinned in the assemblage in such a way that the a thickness of the substrate in the a region between the elevations is between 5 μm and 70 μm inclusive.

10. A semiconductor chip comprising:
a semiconductor body; and
a chip carrier with an interface on which the semiconductor body is fixed, wherein the chip carrier has, on a side facing the semiconductor body, at least one elevation which projects above the semiconductor body in a direction perpendicular to the interface.

11. The semiconductor chip as claimed in claim 10, wherein the chip carrier, in the a region of the semiconductor body, has a thickness of between 10 μm and 30 μm inclusive.

12. The semiconductor chip as claimed in claim 10, wherein the at least one elevation comprises Si.

13. The semiconductor chip as claimed in claim 10, wherein the chip carrier has comprises a carrier part and a stabilization part, connected to the carrier part by a fixing layer, and wherein the interface runs in a separating plane between the carrier part and the stabilization part.

14. The semiconductor chip as claimed in claim 10, wherein the chip carrier is embodied in integral fashion.

15. A semiconductor chip produced in accordance with a method as claimed in claim 1.
